(19) United States
(12) Patent Application Publication
(10) Pub. No.: US 2025/0140616 A1
(43) Pub. Date: May 1, 2025

(54) SEMICONDUCTOR SYSTEM AND METHOD FOR MANUFACTURING THE SAME

(71) Applicant: INNOSCIENCE (SUZHOU) SEMICONDUCTOR CO., LTD., Jiangsu (CN)

(72) Inventors: Shan YIN, Guangdong (CN); Shoudong JIN, Guangdong (CN); Xiong XIN, Guangdong (CN); Yiming LIN, Guangdong (CN); King-Yuen WONG, Guangdong (CN)

(73) Assignee: INNOSCIENCE (SUZHOU) SEMICONDUCTOR CO., LTD., Jiangsu (CN)

(21) Appl. No.: 18/681,855

(22) PCT Filed: Oct. 17, 2022
(86) PCT No.: PCT/CN2022/125606

§ 371 Date: Feb. 6, 2024

(51) Int. Cl. H01L 21/66; H01L 21/67

(52) U.S. Cl. CPC H01L 22/14; H01L 21/67242

(57) ABSTRACT

The present disclosure provides a semiconductor system. The semiconductor system includes a testing circuit, a signaling circuit, and a power circuit. The testing circuit is electrically connected to a semiconductor device. The testing circuit is configured to test a parameter of the semiconductor device. The signaling circuit is electrically connected to the testing circuit. The signaling circuit is configured to receive a first control signal from a processor. The processor is configured to generate the first control signal. The power circuit is electrically connected to the testing circuit. The signaling circuit, the testing circuit and the power circuit are physically separated with one another.

### BACKGROUND

### 1. Technical Field

The present disclosure relates to a semiconductor system and manufacturing method thereof, and more particularly to a semiconductor system and manufacturing method thereof for testing parameters of a semiconductor device.

### 2. Description of the Related Art

Components including direct bandgap semiconductors, for example, semiconductor components including group III-V materials or group III-V compounds (Category: III-V compounds) can operate or work under a variety of conditions or in a variety of environments (e.g., at different voltages and frequencies) due to their characteristics.

The semiconductor components may include a heterojunction bipolar transistor (HBT), a heterojunction field effect transistor (HFET), a high-electron-mobility transistor (HEMT), a modulation-doped FET (MODFET), and the like.

### SUMMARY

In some embodiments of the present disclosure, a semiconductor system is provided, including a testing circuit, a signaling circuit, and a power circuit. The testing circuit is electrically connected to a semiconductor device. The testing circuit is configured to test parameters of the semiconductor device. The signaling circuit is electrically connected to the testing circuit. The signaling circuit is configured to receive a first control signal from a processor. The processor is configured to generate the first control signal. The power circuit is electrically connected to the testing circuit. The signaling circuit, the testing circuit, and the power circuit are physically separated from one another.

In some embodiments of the present disclosure, a semiconductor system for testing a semiconductor device is provided. The semiconductor system includes a signaling circuit and a testing circuit. The testing circuit includes a buffer and a diode. The signaling circuit is configured to receive a first control signal from a processor. The testing circuit is electrically connected to the signaling circuit. The buffer is configured to transmit a fourth control signal to a second electrode of the semiconductor device. The fourth control signal includes voltages higher than those of the third control signal. The diode is electrically connected to a first electrode of the semiconductor device. Dynamic electrical testing of the semiconductor device consists of turning the diode on and off to switch the device.

In some embodiments of the present disclosure, a method for manufacturing a semiconductor system is provided. The method includes forming a testing circuit electrically connected to a semiconductor device, wherein the testing circuit is configured to test parameters of the semiconductor device, forming a signaling circuit electrically connected to the testing circuit, wherein the signaling circuit is configured to receive a first control signal from a processor, wherein the processor is configured to generate the first control signal, and forming a power circuit, electrically connected to the testing circuit, wherein the signaling circuit, the testing circuit, and the power circuit are physically separated.

The proposed semiconductor system allows certain hardware components such as the signal generator and the power supply to be replaced, reducing manufacturing costs. The proposed semiconductor system can also improve measurement accuracy by performing signal isolation and power isolation. Additionally, several units or circuits within the proposed semiconductor system can be physically separated. Therefore, testing flexibility can be achieved without sacrificing measurement accuracy. Moreover, the proposed semiconductor system is compatible with different packages and drive voltages, accelerating system development and reducing maintenance costs.

### BRIEF DESCRIPTION OF THE DRAWINGS

Aspects of the present disclosure are readily understood from the following detailed description when read with the accompanying figures. It should be noted that various features may not be drawn to scale. In fact, the dimensions of the various features may have arbitrarily increased or reduced for clarity of discussion.

FIG. 1A is a schematic circuit diagram of a semiconductor system according to some embodiments of the present disclosure;

FIG. 1B is a cross-sectional view of a semiconductor device according to some embodiments of the present disclosure;

FIG. 2A is another schematic circuit diagram of a semiconductor system according to some embodiments of the present disclosure;

FIG. 2B is schematic illustrating the signal of the processor of a semiconductor system according to some embodiments of the present disclosure;

FIG. 3A is a schematic circuit diagram of a semiconductor system according to some embodiments of the present disclosure;

FIG. 3B is a schematic circuit diagram of a power isolator according to some embodiments of the present disclosure;

FIG. 4 illustrates operations in the manufacture of a semiconductor system according to some embodiments of the present disclosure.

### DETAILED DESCRIPTION

The following disclosure provides for many different embodiments, or examples, for implementing different features of the provided subject matter. Specific examples of components and arrangements are described below. These are, of course, merely examples and are not intended to be limiting. In the present disclosure, reference to the formation of a first feature over or on a second feature in the description that follows may include embodiments in which the first and second features are formed in direct contact, and may also include embodiments in which additional features may have formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Embodiments of the present disclosure are discussed in detail below. It should be appreciated, however, that the present disclosure provides many applicable concepts that can be embodied in a wide variety of specific contexts.

The specific embodiments discussed are merely illustrative and do not limit the scope of the disclosure.

A direct band gap material, such as a group III-V compound may include, but is not limited to, gallium arsenide (GaAs), indium phosphide (InP), gallium nitride (GaN), Indium gallium arsenide (InGaAs), Indium aluminum arsenide (InAlAs), and the like.

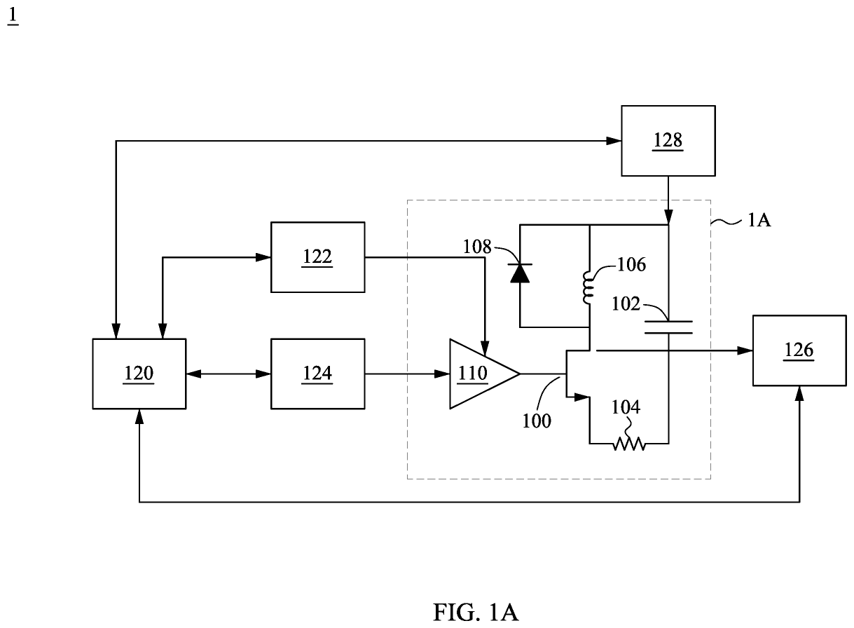

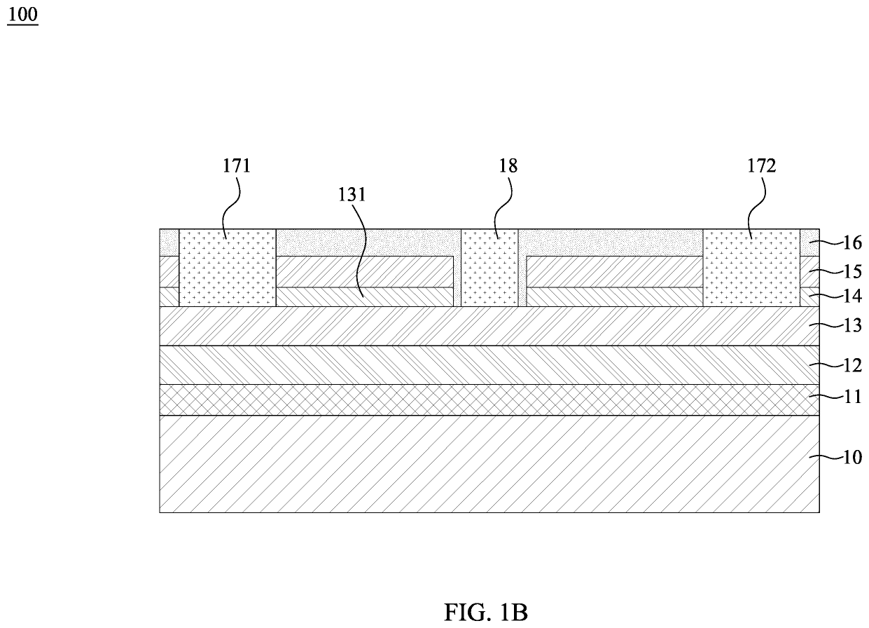

FIG. 1A is a schematic circuit diagram of a semiconductor system 1 according to some embodiments of the present disclosure. As shown in FIG. 1A, the semiconductor system 1 can include a testing circuit 1A, a processor 120, a voltage source 122, a signal generator 124, an oscilloscope 126, and a voltage source 128. More specifically, in some embodiments, the testing circuit 1A can include a semiconductor device 100, a capacitor 102, a resistor 104, an inductor 106, a diode 108, and a driver 110.

In some embodiments, the testing circuit 1A can be used to test a parameter of the semiconductor device 100. The parameter can include, but is not limited to, a gate turned-on delay (t_{don}). The parameter can include, but is not limited to, a drain voltage decreasing time (tᵣ). The parameter can include, but is not limited to, a gate turned-off delay (t_{doff}). The parameter can include, but is not limited to, a drain voltage increasing time (t_{f}). The parameter can include, but is not limited to, a turned-on energy (Eₒₙ). The parameter can include, but is not limited to, a turned-off energy (E_{off}).

In some embodiments, the semiconductor device 100 can include a semiconductor layer. The semiconductor device 100 can include a group III-V semiconductor material. The semiconductor device 100 can include a group III-V dielectric material. The semiconductor device 100 can be a device under test (DUT) which is tested or measured by the semiconductor system 1.

The driver 110 can be used to drive and control the semiconductor device 100. The driver 110 is electrically connected to the gate electrode of the semiconductor device 100. The driver 110 may include a gate driver. A signal can be received by the driver 110 for regulating or operating the semiconductor device in 100. The above signal can include a pulse width modulation (PWM) signal.

The processor 120 can include, but is not limited to, a central processing unit (CPU), a multi-processor, a distributed processing system, an application specific integrated circuit (ASIC), and/or a suitable processing unit. The processor 120 may include, but is not limited to, at least one hardware processor, including at least one microprocessor such as a CPU, a portion of at least one hardware processor, or any other suitable dedicated processor such as those developed based on Field Programmable Gate Array (FPGA) and ASIC.

In some embodiments, the voltage source 122 can provide low voltage to the driver 110. In some embodiments, the voltage source 128 can generate high voltage providing power or energy to the testing circuit 1A. The power or energy can be circulated between the capacitor 102 and the inductor 106. In some embodiments, the signal generator 124 can generate and transmit a PWM signal to the driver 110. The oscilloscope 126 can be used to monitor or evaluate the electrical testing of the semiconductor device 100. The processor 120 can be used to control or analyze the electrical testing of the semiconductor device 100 in association with the signal generator 124, the voltage sources 122 and 128, and the oscilloscope 126.

In some embodiments, dynamic electrical testing can be executed by the testing circuit 1A. The dynamic electrical testing can be performed on the semiconductor device 100 by turning the diode 108 on and off for switching the semiconductor device 100. The semiconductor device 100 can be turned on and turned off continuously to measure the mentioned parameters.

FIG. 1B is a cross-sectional view of the semiconductor device 100 according to some embodiments of the present disclosure. As shown in FIG. 1B, the semiconductor device 100 may include a substrate 10, a buffer layer 11, a semiconductor layer 12, a semiconductor layer 13, a group III-V dielectric layer 14, a passivation layer 15, a passivation layer 16, a conductive structure 171, a conductive structure 172, and a conductive structure 18.

The substrate 10 may include, for example, but is not limited to, silicon (Si), doped silicon (doped Si), silicon carbide (Sic), germanium silicide (SiGe), gallium in 5 arsenide (GaAs), or another semiconductor material. In some embodiments, the substrate 10 may include an intrinsic semiconductor material. In some embodiments, the substrate 10 may include a p-type semiconductor material. In some embodiments, the substrate 10 may include a silicon layer doped with boron (B). In some embodiments, the substrate 10 may include a silicon layer doped with gallium (Ga). In some embodiments, the substrate 10 may include an n-type 10 semiconductor material. In some embodiments, the substrate 10 may include a silicon layer doped with arsenic (As). In some embodiments, the substrate 10 may include a silicon layer doped with phosphorus (P).

The buffer layer 11 may be disposed on the substrate 10. In some embodiments, the buffer layer 11 may include nitrides. In some embodiments, the buffer layer 11 may include, for example, but is not limited to, aluminum nitride (AlN). In some embodiments, the buffer layer 11 may include, for example, but is not limited to, aluminum gallium nitride (AlGaN). The buffer layer 11 may include a multilayer structure. The buffer layer 11 may include a superlattice layer with periodic structure of two or more materials. The buffer layer 11 may include a single layer structure.

The semiconductor layer 12 may be disposed on the buffer layer 11. The semiconductor layer 12 may include group III-V materials. The semiconductor layer 12 may be a nitride semiconductor layer. The semiconductor layer 12 may include, for example, but is not limited to, group III nitride. The semiconductor layer 12 may include, for example, but is not limited to, GaN. The semiconductor layer 12 may include, for example, but is not limited to, AlN. The semiconductor layer 12 may include, for example, but is not limited to, InN. The semiconductor layer 12 may include, for example, but is not limited to, compound InₓAl_{y}Ga_{1-x-y}N, where x+y≤1. The semiconductor layer 12 may include, for example, but is not limited to, compound Al_{y}Ga_{(1-y)}N, where y≤1.

The semiconductor layer 13 may be disposed on the semiconductor layer 12. The semiconductor layer 13 may include group III-V materials. The semiconductor layer 13 may be a nitride semiconductor layer. The semiconductor layer 13 may include, for example, but is not limited to, group III nitride. The semiconductor layer 13 may include, for example, but is not limited to, compound Al_{y}Ga_{(1-y)}N, where y≤1. The semiconductor layer 13 may include, for example, but is not limited to, GaN. The semiconductor layer 13 may include, for example, but is not limited to, AlN. The semiconductor layer 13 may include, for example, but is not limited to, InN. The semiconductor layer 13 may include, for example, in but is not limited to, compound InₓAl_{y}Ga_{1-x-y}N, where x+y≤1.

A heterojunction may be formed between the semiconductor layer 13 and the semiconductor layer 12. The semiconductor layer 13 may have a band gap greater than a band gap of the semiconductor layer 12. For example, the semiconductor layer 13 may include AlGaN that may have a band gap of about 4 eV, and the semiconductor layer 12 may include GaN that may have a band gap of about 3.4 eV.

In the semiconductor device 100, the semiconductor layer 12 may be used as a channel layer. In the semiconductor device 100, the semiconductor layer 12 may be used as a channel layer disposed on the buffer layer 11. In the semiconductor device 100, the semiconductor layer 13 may be used as a barrier layer. In the semiconductor device 100, the semiconductor layer 13 may be used as a barrier layer disposed on the semiconductor layer 12.

In the semiconductor device 100, because the band gap of the semiconductor layer 12 is less than the band gap of the semiconductor layer 13, two dimensional electron gas (2DEG) may be formed in the semiconductor layer 12. In the semiconductor device 100, because the band gap of the semiconductor layer 12 is less than the band gap of the semiconductor layer 13, 2DEG may be formed in the semiconductor layer 12 and the 2DEG is close to the interface of the semiconductor layer 13 and the semiconductor layer 12. In the semiconductor device 100, because the band gap of the semiconductor layer 13 exceeds the band gap of the semiconductor layer 12, 2DEG may be formed in the semiconductor layer 12. In the semiconductor device 100, because the band gap of the semiconductor layer 13 exceeds the band gap of the semiconductor layer 12, 2DEG may be formed in the semiconductor layer 12 and the 2DEG is close to the interface of the semiconductor layer 13 and the semiconductor layer 12.

The group III-V dielectric layer 14 may be disposed on the semiconductor layer 13. The group III-V dielectric layer 14 may be in direct contact with the semiconductor layer 13. The group III-V dielectric layer 14 may separate the conductive structure 18 from the conductive structure 171. The group III-V dielectric layer 14 may separate the conductive structure 18 from the conductive structure 172. The group III-V dielectric layer 14 may include nitride. The group III-V dielectric layer 14 may include, but is not limited to, AlN. The group III-V dielectric layer 14 may include, but is not limited to, boron nitride (BN). The group III-V dielectric layer 14 may electrically isolate the conductive structure 18. The group III-V dielectric layer 14 may electrically isolate the conductive structure 171. The group III-V dielectric layer 14 may electrically isolate the conductive structure 172. The group III-V dielectric layer 14 may have a thickness between approximately 1 nm and approximately 10 nm. The group III-V dielectric layer 14 may have a thickness between approximately 3 nm and approximately 8 nm. The group III-V dielectric layer 14 may have a thickness of about 5 nm.

The passivation layer 15 may be disposed on the semiconductor layer 13. The passivation layer 15 may extend over the semiconductor layer 13. The passivation layer 15 may be disposed on the group III-V dielectric layer 14. The passivation layer 15 may cover the group III-V dielectric layer 14. The passivation layer 15 may extend along the group III-V dielectric layer 14. The passivation layer 15 may be in direct contact with the group III-V dielectric layer 14. The passivation layer 15 may separate the conductive structure 18 from the conductive structure 171. The passivation layer 15 may separate the conductive structure 18 from the conductive structure 172. The passivation layer 15 may include a dielectric material. The passivation layer 15 may include a non-group III-V dielectric material. The passivation layer 15 may include nitride. The passivation layer 15 may include, but is not limited to, silicon nitride (Si₃N₄). The passivation layer 15 may include oxide. The passivation layer 15 may include, but is not limited to, silicon oxide (SiO₂). The passivation layer 15 may electrically isolate the conductive structure 18. The passivation layer 15 may electrically isolate the conductive structure 171. The passivation layer 15 may electrically isolate the conductive structure 172. The passivation layer 15 may have a thickness between approximately 10 nm and approximately 100 nm. The passivation layer 15 may have a thickness between approximately 30 nm and approximately 70 nm. The passivation layer 15 may have a thickness of about 50 nm.

The passivation layer 16 may be disposed on the semiconductor layer 13. The passivation layer 16 may extend over the semiconductor layer 13. The passivation layer 16 may be disposed on the group III-V dielectric layer 14. The passivation layer 16 may cover the group III-V dielectric layer 14. The passivation layer 16 may cover the sidewall of the group III-V dielectric layer 14. The passivation layer 16 may extend along the group III-V dielectric layer 14. The passivation layer 16 may surround the group III-V dielectric layer 14. The passivation layer 16 may be in direct contact with the group III-V dielectric layer 14. The passivation layer 16 may be in direct contact with the sidewall of the group III-V dielectric layer 14. The passivation layer 16 may be disposed on the passivation layer 15. The passivation layer 16 may cover the passivation layer 15. The passivation layer 16 may cover the sidewall of the passivation layer 15. The passivation layer 16 may extend along the passivation layer 15. The passivation layer 16 may surround the passivation layer 15. The passivation layer 16 may be in direct contact with the passivation layer 15. The passivation layer 16 may be in direct contact with the sidewall of the passivation layer 15. The passivation layer 16 may be in direct contact with the conductive structure 18. The passivation layer 16 may separate the conductive structure 18 from the conductive structure 171. The passivation layer 16 may separate the conductive structure 18 from the conductive structure 172. The passivation layer 16 may separate the conductive structure 18 from the group III-V dielectric layer 14. The passivation layer 16 may separate the conductive structure 18 from the passivation layer 15. The passivation layer 16 may include a dielectric material. The passivation layer 16 may include a non-group III-V dielectric material. The passivation layer 16 may include nitride. The passivation layer 16 may include, but is not limited to, Si₃N₄. The passivation layer 16 may include oxide. The passivation layer 16 may include, but is not limited to, SiO₂. The passivation layer 16 may electrically isolate the conductive structure 18. The passivation layer 16 may electrically isolate the conductive structure 171. The passivation layer 16 may electrically isolate the conductive structure 172. The passivation layer 16 may have a thickness between approximately 1 nm and approximately 100 nm. The passivation layer 16 may have a thickness between approximately 30 nm and approximately 70 nm. The passivation layer 16 may have a thickness of about 50 nm.

The passivation layer 16 may be of a material different from that of the group III-V dielectric layer 14. The passivation layer 16 may be of a material different from that of the passivation layer 15. The passivation layer 16 may be of a material identical to that of the passivation layer 15. As the passivation layer 16 and the passivation layer 15 have the same material, the passivation layer 16 and the passivation layer 15 may be regarded as a single layer. For example, the group III-V dielectric layer 14 may include AlN, the passivation layer 15 may include SiO₂ and the passivation layer 16 may include Si₃N₄. For example, the group III-V dielectric layer 14 may include AlN, the passivation layer 15 may include Si₃N₄ and the passivation layer 16 may include Si₃N₄. For example, the group III-V dielectric layer 14 may include AlN, the passivation layer 15 may include SiO₂ and the passivation layer 16 may include SiO₂. For example, the group III-V dielectric layer 14 may include BN, the passivation layer 15 may include SiO₂ and the passivation layer 16 may include Si₃N₄. For example, the group III-V dielectric layer 14 may include BN, the passivation layer 15 may include Si₃N₄ and the passivation layer 16 may include Si₃N₄. For example, the group III-V dielectric layer 14 may include BN, the passivation layer 15 may include SiO₂ and the passivation layer 16 may include SiO₂.

The conductive structure 171 may be disposed on the semiconductor layer 13. The conductive structure 171 may contact the semiconductor layer 13. The conductive structure 171 may be electrically connected to the semiconductor layer 12. The conductive structure 171 may be electrically connected to the semiconductor layer 12 through the semiconductor layer 13. The conductive structure 171 may be surrounded by the group III-V dielectric layer 14. The conductive structure 171 may be surrounded by the passivation layer 15. The conductive structure 171 may be surrounded by the passivation layer 16. The conductive structure 171 may include a conductive material. The conductive structure 171 may include a metal. The conductive structure 171 may include, but is not limited to, Al. The conductive structure 171 may include, but is not limited to, Ti. The conductive structure 171 may include a metal compound. The conductive structure 171 may include, but is not limited to, titanium nitride (TiN).

The conductive structure 172 may be disposed on the semiconductor layer 13. The conductive structure 172 may contact the semiconductor layer 13. The conductive structure 172 may be electrically connected to the semiconductor layer 12. The conductive structure 172 may be electrically connected to the semiconductor layer 12 through the semiconductor layer 13. The conductive structure 172 may be surrounded by the group III-V dielectric layer 14. The conductive structure 172 may be surrounded by the passivation layer 15. The conductive structure 172 may be surrounded by the passivation layer 16. The conductive structure 172 may include a conductive material. The conductive structure 172 may include a metal. The conductive structure 172 may include, but is not limited to, Al. The conductive structure 172 may include, but is not limited to, Ti. The conductive structure 172 may include a metal compound. The conductive structure 172 may include, but is not limited to, AlN. The conductive structure 172 may include, but is not limited to, TiN.

In the semiconductor device 100, the conductive structure 171 may be used as, for example, but is not limited to, a source electrode. In the semiconductor device 100, the conductive structure 171 may be used as, for example, but is not limited to, a drain electrode.

In the semiconductor device 100, the conductive structure 172 may be used as, for example, but is not limited to, a drain electrode. In the semiconductor device 100, the conductive structure 172 may be used as, for example, but is not limited to, a source electrode.

The conductive structure 18 may be disposed on the semiconductor layer 13. The conductive structure 18 may be in direct contact with the semiconductor layer 13. The conductive structure 18 may be surrounded by the passivation layer 16. The conductive structure 18 may be separated from the group III-V dielectric layer 14. The conductive structure 18 may be separated from the group III-V dielectric layer 14 by the passivation layer 16. The conductive structure 18 may include a metal. The conductive structure 18 may include, for example, but is not limited to, gold (Au), platinum (Pt), titanium (Ti), palladium (Pd), nickel (Ni), or tungsten (W). The conductive structure 18 may include a metal compound. The conductive structure 18 may include, for example, but is not limited to, TiN.

In the semiconductor device 100, the conductive structure 18 may be used as a gate electrode. In the semiconductor device 100, the conductive structure 18 may be configured to control the 2DEG in the semiconductor layer 12. In the semiconductor device 100, a voltage may be applied to the conductive structure 18 to control the 2DEG in the semiconductor layer 12. In the semiconductor device 100, a voltage may be applied to the conductive structure 18 to control the 2DEG in the semiconductor layer 12 and below the conductive structure 18. In the semiconductor device 100, a voltage may be applied to the conductive structure 18 to control connection or disconnection between the conductive structure 171 and the conductive structure 172.

It should be noted that the conductive structure 171 may be used as a source electrode of the semiconductor device 100, the conductive structure 172 may be used as a drain electrode of the semiconductor device 100, and the conductive structure 18 may be used as a gate electrode of the semiconductor device 100. However, the conductive structure 171, the conductive structure 172, and the conductive structure 18 may be disposed differently in other embodiments of the disclosure according to design requirements.

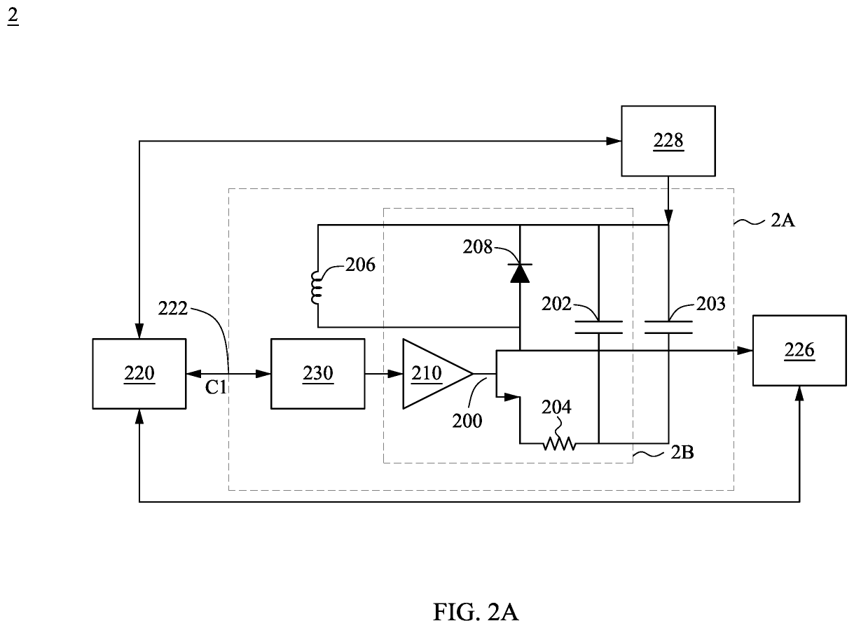

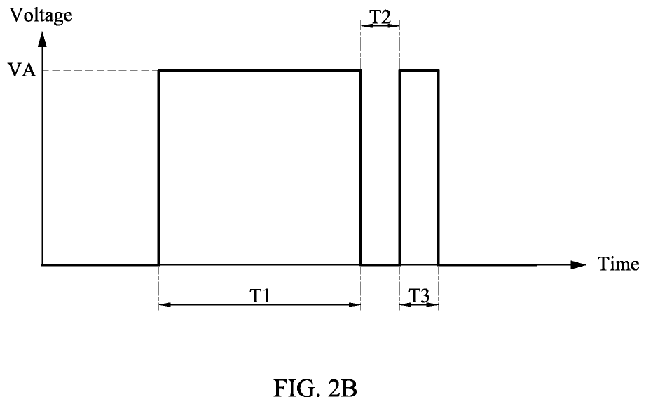

FIG. 2A is another schematic circuit diagram of a semiconductor system 2 according to some embodiments of the present disclosure. The semiconductor system 2 of FIG. 2A is similar to the semiconductor system 1 of FIG. 1A, except for the differences described as follows.

As shown in FIG. 2A, the semiconductor system 2 can include a testing circuit 2A, a processor 220, a voltage source 228, and an oscilloscope 226. Specifically, the testing circuit 2A can include a core circuit 2B, a controller 230, an inductor 206, and a capacitor 203. More specifically, in some embodiments, the core circuit 2B can include a semiconductor device 200, a capacitor 202, a resistor 204, a diode 208, and a driver 210.

In some embodiments, the core circuit 2B can be critical to the electrical characteristics of the semiconductor device 200, and thus can be of an independent layout. The core circuit 2B can be electrically coupled to a circuit board or a motherboard through a connecting component.

In some embodiments, the controller 230 can be electrically connected to the processor 220 through a universal serial bus (USB) 222 for receiving power or energy. The controller 230 can receive a control signal C1 from the processor 220. The control signal C1 can include a PWM signal. The controller 230 can be used to provide a voltage to the core circuit 2B.

The controller 230 can include a digital signal processor (DSP), a microcontroller (MCU), a central-processing unit (CPU) or a plurality of parallel processors relating the parallel processing environment to implement the operating system (OS), firmware, driver and/or other applications of the semiconductor system. Compared to the semiconductor system 1 of FIG. 1A, the signal generator 124 and the power supply 122 can be replaced by the controller 230 to reduce manufacturing costs.

The capacitor 202 can be electrically connected in parallel with the capacitor 203. The capacitor 202 can be closer to the semiconductor device 200 than the capacitor 203. The capacitance of the capacitor 202 can be lower than the capacitance of the capacitor 203. The capacitance of the capacitor 202 can be substantially equal to the capacitance of the capacitor 203. The capacitance of the capacitor 202 can exceed the capacitance of the capacitor 203.

In some embodiments, the capacitor 202 can include a thin-film capacitor. The capacitor 202 can include a multi-layer ceramic capacitor (MLCC). The capacitor 202 can have low parasitic inductance and capacitance. The capacitor 202 can be used to realize high-speed response to charge and discharge. In some embodiments, the capacitor 203 can include an electrolytic capacitor. The capacitor 203 can have high capacitance. The capacitor 203 can be used to stabilize the high direct-current power supply.

FIG. 2B is a schematic illustrating the control signal C1 of the processor 220 of the semiconductor system 2 according to some embodiments of the present disclosure.

As shown in FIG. 2B, the control signal C1 can include a high voltage level corresponding to the voltage of VA, and include a low voltage level corresponding to the voltage of 0V. During duration T1, the control signal C1 can be at a high voltage level. During duration T2, the control signal C1 can be at a low voltage level. In addition, during duration T3, the control signal C1 can be at a high voltage level.

In some embodiments, the durations T1, T2 and T2 can be adjusted or controlled independently by the processor 220. The voltage of VA can be adjusted or controlled independently by the processor 220. The control signal C1 is generated by the processor 220 and transmitted to the controller 230 in order to enable or disable the semiconductor device 200.

For example, the semiconductor device 200 can be turned on when the control signal is at high voltage level, and the semiconductor device 200 can be turned off when the control signal is at low voltage level. For example, the semiconductor device 200 can be turned on when the control signal is at low voltage level, and the semiconductor device 200 can be turned off when the control signal is at high voltage level.

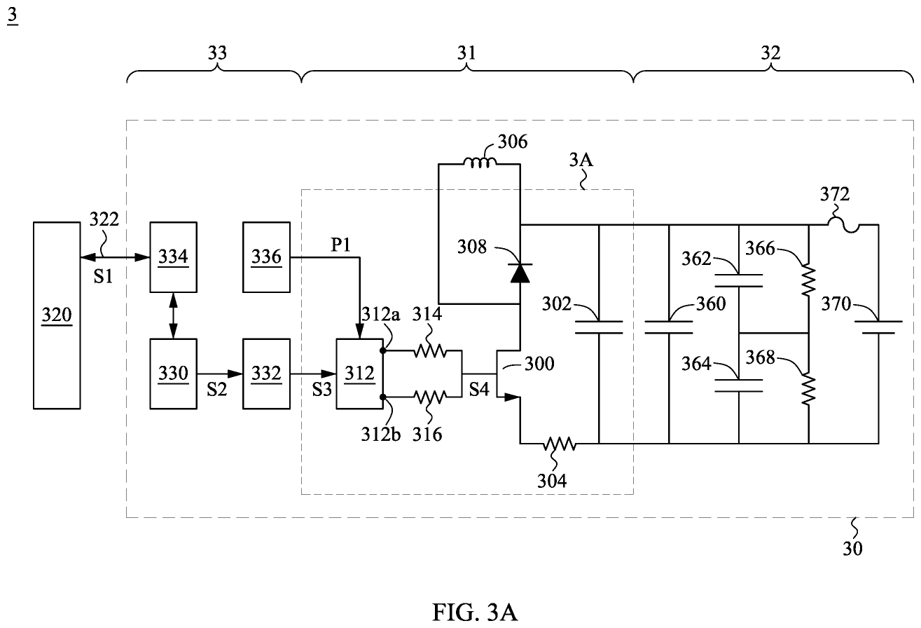

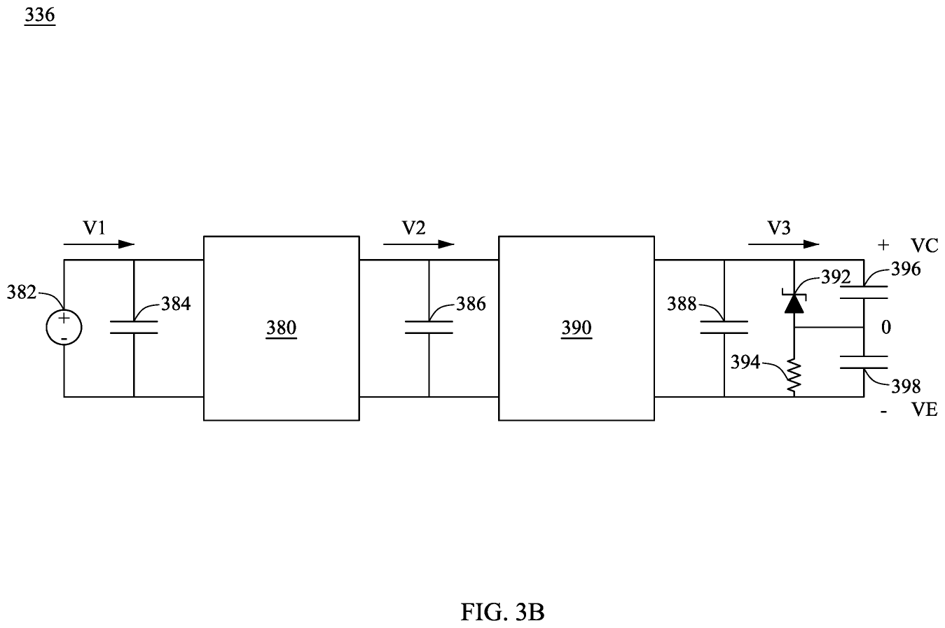

FIG. 3A is a schematic circuit diagram of a semiconductor system 3 according to some embodiments of the present disclosure. The semiconductor system 3 of FIG. 3A is similar to the semiconductor system 2 of FIG. 2A, except for the differences described as follows.

The semiconductor system 3 can include a testing circuit 31, a power circuit 32, a signaling circuit 33 and a processor 320. As shown in FIG. 3A, the signaling circuit 33 can include a controller 330, a signal isolator 332, a converter 334 and a power isolator 336. The testing circuit 31 can include a core circuit 3A and an inductor 306. The core circuit 3A may include a semiconductor device 300, a capacitor 302, a diode 308, a buffer 312, and two resistors 314 and 316. The power circuit 32 can include three capacitors 360, 362, 364, two resistors 366 and 368, a voltage source 370 and a fuse 372.

In some embodiments, the signaling circuit 33, the testing circuit 31, and in 5 the power circuit 32 are physically separated. Therefore, testing flexibility can be achieved without sacrificing measurement accuracy. Compatibility with different packages and drive voltages can also be arrived at by the semiconductor system 3.

In some embodiments, the signaling circuit 33 can be electrically connected to the testing circuit 31. The signaling circuit 33 can be configured to receive a control signal S1 from the processor 320. The processor 320 can be configured to generate and transmit the control signal S1 to the converter 334. The control signal S1 can correspond to the control signal C1 as illustrated in FIG. 2A and FIG. 2B. The processor 320 can be in electrical communication with the signaling circuit 33 through the USB 322.

In some embodiments, the converter 334 can be electrically connected to the processor 320. The converter 334 can receive the control signal S1 from the processor 320 through the USB 322. The converter 334 can obtain power or energy from the processor 320 through the USB 322. In some embodiments, the controller 330 can be electrically connected to the converter 334. The controller 330 can be configured to provide a control signal S2 to the signal isolator 332. The control 20 signal S2 can include double pulses.

The signal isolator 332 can be configured to generate a control signal S3 to the buffer 312 of the testing circuit 31. The control signal S3 can be generated corresponding to the control signal S2. The control signal S3 can be used to prevent the controller 330 from interference during testing of the semiconductor device 300. The control signal S3 can be used to protect the controller 330 from the high-speed switching of the semiconductor device 300. In some embodiments, the power isolator 336 can be configured to provide a power supply P1 to the testing circuit 31. The power supply P1 can be received by the buffer 312. The testing circuit 31 can be powered by the power supply P1 received by the buffer 312.

In some embodiments, the testing circuit 31 can be configured to test parameters of the semiconductor device 300. The semiconductor device 300 can correspond to the semiconductor device 100 of FIG. 1B. As shown in FIG. 3A, the drain electrode of the semiconductor device 300 can be electrically connected to the diode 308 and the inductor 306. The gate electrode of the semiconductor device 300 can be electrically connected to the resistors 314 and 316. The source electrode of the semiconductor device 300 can be electrically connected to the resistor 304.

The buffer 312 can be electrically connected to the gate electrode of the semiconductor device 300 through the resistors 314 and 316. The buffer 312 can correspond to the driver 210 of FIG. 2A. The buffer 312 can be configured to amplify the power signal S3 from the signaling circuit 33. The buffer 312 can provide a control signal S4 to the semiconductor device 300 for controlling or operating the semiconductor device 300. The buffer 312 can provide the control signal S4 in correspondence with the control signal S3.

The resistors 314 and 316 can be arranged between the buffer 312 and the semiconductor device 300. The resistor 314 can be electrically connected between a turn-on output terminal 312a of the buffer 312 and the gate electrode of the semiconductor device 300. The resistor 316 can be electrically connected between the turn-off output terminal 312b of buffer 312 and the gate electrode of the semiconductor device. The resistors 314 and 316 can be configured to regulate the operating speed of the control signal S4.

In some embodiments, the capacitor 302 can be electrically connected between the diode 308 and the source electrode of the semiconductor device 300. The capacitor 302 can include a thin-film capacitor. The capacitor 302 can include a MLCC. The capacitor 302 can have low parasitic inductance and capacitance. The capacitor 302 can be used to implement high-speed operation for the semiconductor device 300. The capacitor 302 can be used to realize high-speed response to charge and discharge.

The capacitor 360 can be electrically connected in parallel with the capacitor 302. The capacitor 360 can be electrically connected between the diode 308 and resistor 304. The capacitor 360 can include a thin-film capacitor. The capacitor 360 can include a MLCC. The capacitor 360 can have low parasitic inductance and capacitance. The capacitor 360 can be used to implement high-speed operation for the semiconductor device 300. The capacitor 360 can be used to implement high-speed operation for the semiconductor device 300. The capacitor 360 can be used to realize high-speed response to charge and discharge.

The capacitor 362 can be electrically connected to the diode 308. The capacitor 364 can be electrically connected in series with the capacitor 362. The capacitor 364 can be electrically connected to the source electrode of the semiconductor device 300. The capacitors 362 and 364 can be configured to maintain the power supply for the testing circuit 31. Each of the capacitors 362 and 364 can include an electrolytic capacitor. Each of the capacitors 362 and 364 can have high capacitance. The capacitors 362 and 364 can be used to stabilize the high direct-current power supply.

In some embodiments, the capacitance of the capacitor 302 can be lower than the capacitance of the capacitor 360. The capacitance of the capacitor 360 can be lower than the capacitance of the capacitor 362. The capacitance of the capacitor 360 can be lower than the capacitance of the capacitor 364. The capacitance of the capacitor 362 can be substantially identical to the capacitance of the capacitor 364. The capacitance of the capacitor 362 can be different from the capacitance of the capacitor 364. The series capacitance of the capacitors 362 and 364 can be expressed as follows.

$$C = \frac{L \times {I}^{2}}{2 \times V d c \times ΔV d c}$$

Note that C can be the series capacitance of the capacitors 362 and 364. L can be the inductance of the inductor 306. I can be the current of the semiconductor device 300 (DUT). Vdc can be the voltage of the DUT or the voltage of the voltage source 370. ΔVdc can be the ripple or surge of the voltage Vdc.

In some embodiments, the resistor 366 can be electrically connected in parallel with the capacitor 362. The resistor 368 can be electrically connected in parallel with the capacitor 364. The resistor 368 can be electrically connected in series with the resistor 366. The resistors 366 and 368 can be used to develop and maintain voltages applied or divided to the capacitors 362 and 364. In some embodiments, the fuse 372 can be used to protect the semiconductor system 3 from abnormal damage.

FIG. 3B is a schematic circuit diagram of the power isolator 336 according to some embodiments of the present disclosure. As shown in FIG. 3B, the power isolator 336 can include a power unit 380, a voltage source 382, five capacitors 384, 386, 388, 396 and 398, a power unit 390, a diode 392, and a resistor 394.

The power isolator 336 can be configured to provide the power supply P1 to the testing circuit 31, as shown in FIG. 3A. In some embodiments shown in FIG. 3B, the power unit 380 can be arranged between the capacitors 384 and 386. The power unit 380 can be configured to adjust the power supply voltage V1 for generating a power supply voltage V2. The power supply voltage V1 can be provided by the voltage source 382, where the power supply can be obtained from the processor 320 through the USB 322. The power supply voltage V1 can be applied to the capacitor 384 so that the capacitor 384 may store charges. The power supply voltage V2 can be applied to the capacitor 386 so that the capacitor 386 may store charges.

In some embodiments, the power unit 390 can be arranged between the capacitors 386 and 388. The power unit 390 can be electrically connected to the power unit 380. The power unit 390 can be configured to generate power supply voltage V3 corresponding to the power supply voltage V2. Power supply voltage V3 can flow into or be stored by the capacitor 388.

The diode 392 can be electrically connected in parallel with the capacitor 396. The diode 392 can include a Zener diode. The resistor 394 can be electrically connected in parallel with the capacitor 398. The resistor 394 can be electrically connected in series with the diode 392. The diode 392 and the resistor 394 are configured to provide a positive voltage VC and a negative voltage VE in association with the power unit 390. The positive voltage VC can be included by the power supply P1. The negative voltage VE can be included by the power supply P1. The positive voltage VC and the negative voltage VE can both be included by the power supply P1.

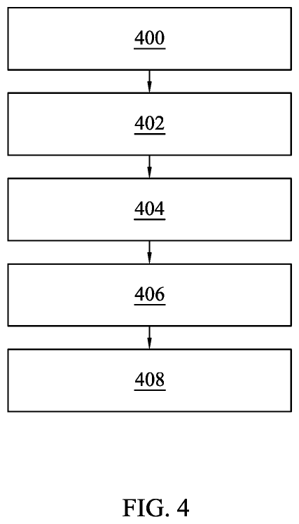

FIG. 4 illustrates operations in the manufacture of a semiconductor system according to some embodiments of the present disclosure. In operation 400, a testing circuit can be formed for electrically connecting to a semiconductor device. The testing circuit is configured to test parameters of the semiconductor device. In operation 402, a signaling circuit can be formed for electrically connecting to the testing circuit.

Furthermore, in operation 404, a power circuit is formed for electrically connecting to the testing circuit. In operation 406, dynamic electrical testing can be performed on the semiconductor device. In operation 408, the parameters obtained from the dynamic electrical testing on the semiconductor device can be analyzed.

While disclosed methods or operations are illustrated and described herein as a series of acts or events, it will be appreciated that the illustrated ordering of such acts or events are not to be interpreted in a limiting sense. For example, some operations may occur in different order and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

As used herein, spatially relative terms, such as “beneath,” “below,” “lower,” “above,” “upper,” “higher,” “left,” “right” and the like, may be used herein for ease of description to describe one element or feature's relationship to other elements or features as illustrated in the figures. The spatially relative terms are intended to encompass different orientations of the device in use or operation in addition to the orientation depicted in the figures. The apparatus may be otherwise oriented (rotated 90° or at other orientations) and the spatially relative descriptors used herein may likewise be interpreted accordingly. It should be understood that when an element is referred to as being “connected to” or “coupled to” another element, it may be directly connected to or coupled to the other element, or intervening elements may be present.

As used herein, the terms “approximately,” “substantially,” “substantial” and “about” are used to describe and account for small variations. When used in conduction with an event or circumstance, the terms can refer to instances in which the event of circumstance occurs precisely as well as instances in which the event or circumstance occurs to a close approximation. As used herein with respect to a given value or range, the term “about” generally means within ±10%, ±5%, ±1%, or ±0.5% of the given value or range. Ranges can be expressed herein as from one endpoint to another endpoint or between two endpoints. All ranges disclosed herein are inclusive of the endpoints, unless specified otherwise. The term “substantially coplanar” can refer to two surfaces within micrometers (μm) of lying along a same plane, such as within 10 μm, within 5 μm, within 1 μm, or within 0.5 μm of lying along the same plane. When referring to numerical values or characteristics as “substantially” the same, the term can refer to the values lying within ±10%, ±5%, ±1%, or ±0.5% of an average of the values.

Several embodiments of the disclosure and features of details are briefly described here. The embodiments described in the disclosure may be easily used as a basis for designing or modifying other processes and structures for realizing the same or similar objectives and/or obtaining the same or similar advantages introduced in the embodiments of the disclosure. Such equivalent constructions do not depart from the spirit and scope of the disclosure, and various variations, replacements, and modifications can be made without departing from the spirit and scope of the disclosure.

1. A semiconductor system, comprising:
a testing circuit, electrically connected to a semiconductor device, wherein the testing circuit is configured to test a parameter of the semiconductor device;
a signaling circuit, electrically connected to the testing circuit, wherein the signaling circuit is configured to receive a first control signal from a processor, wherein the processor is configured to generate the first control signal; and
a power circuit, electrically connected to the testing circuit, wherein the signaling circuit, the testing circuit, and the power circuit are physically separated with one another.

2. The semiconductor system of claim 1, wherein the testing circuit further comprises:
a first diode, electrically connected to a first electrode of the semiconductor device; and
a buffer, electrically connected to a second electrode of the semiconductor device, wherein the buffer is configured to amplify a third control signal from the signaling circuit and provide a fourth control signal to the semiconductor device.

3. The semiconductor system of claim 2, wherein the testing circuit further comprises:
a first capacitor, electrically connected between the first diode and a third electrode of the semiconductor device;
a first resistor, electrically connected between a turn-on output terminal of the buffer and the second electrode of the semiconductor device; and
a second resistor, connected between a turn-off output terminal of the buffer and the second electrode of the semiconductor device, wherein the first resistor and the second resistor are configured to regulate an operating speed of the fourth control signal.

4. The semiconductor system of claim 3, wherein the power circuit comprises:
a second capacitor, electrically connected in parallel with the first capacitor to implement a high-speed operation for the semiconductor device;
a third capacitor, electrically connected to the first diode; and
a fourth capacitor, connected in series with the third capacitor and electrically connected to the third electrode of the semiconductor device, wherein the third capacitor and the fourth capacitor are configured to maintain a power supply.

5. The semiconductor system of claim 4, wherein a capacitance of the first capacitor is lower than a capacitance of the second capacitor, and the capacitance of the second capacitor is lower than that of the third capacitor.

6. The semiconductor system of claim 4, wherein the power circuit comprises:
a third resistor, connected in parallel with the third capacitor; and
a fourth resistor, connected in parallel with the fourth capacitor.

7. The semiconductor system of claim 2, wherein the power circuit comprises:
an inductor, electrically connected in parallel with the first diode of the testing circuit.

8. The semiconductor system of claim 1, wherein the signaling circuit comprises:
a converter, electrically connected to the processor; and
a controller, electrically connected to the converter, wherein the controller is configured to provide a second control signal comprising double pulses.

9. The semiconductor system of claim 8, wherein the signaling circuit comprises:
a signal isolator, configured to generate a third control signal corresponding to the second control signal and prevent the controller from being interfered during testing of the semiconductor device.

10. The semiconductor system of claim 8, wherein the signaling circuit comprises:
a power isolator, configured to provide a power supply to the testing circuit.

11. The semiconductor system of claim 10, wherein the power isolator comprises:
a first power unit, configured to adjust a first power supply voltage for generating a second power supply voltage; and
a second power unit, electrically connected to the first power unit, wherein the second power unit is configured to generate a third power supply voltage corresponding to the second power supply voltage.

12. The semiconductor system of claim 11, wherein the power isolator comprises:
a second diode, wherein the second diode comprises a Zener diode; and
a fifth resistor, connected in series with the second diode, wherein the second diode and the fifth resistor are configured to provide a positive voltage and a negative voltage in association with the second power unit.

13. The semiconductor system of claim 1, wherein the signaling circuit is electrically connected to the processor through a universal serial bus.

14. The semiconductor system of claim 3, wherein the semiconductor device comprises:
a substrate;
a first nitride semiconductor layer on the substrate;
a second nitride semiconductor layer on the first nitride semiconductor layer, wherein a band gap of the second nitride semiconductor layer is exceeding that of the first nitride semiconductor layer.

15. The semiconductor system of claim 14, wherein the first electrode, the second electrode, and the third electrode of the semiconductor device are formed on the second nitride semiconductor layer.

16. A method for manufacturing a semiconductor system, comprising:
forming a testing circuit electrically connected to a semiconductor device, wherein the testing circuit is configured to test a parameter of the semiconductor device;
forming a signaling circuit electrically connected to the testing circuit, wherein the signaling circuit is configured to receive a first control signal from a processor, wherein the processor is configured to generate the first control signal; and
forming a power circuit, electrically connected to the testing circuit, wherein the signaling circuit, the testing circuit, and the power circuit are physically separated with one another.

17. The method of claim 16, further comprising:
forming a first diode, electrically connected to a first electrode of the semiconductor device; and
forming a buffer electrically connected to a second electrode of the semiconductor device, wherein the buffer is configured to amplify a third control signal from the signaling circuit and provide a fourth control signal to the semiconductor device.

18. The method of claim 16, further comprising:
forming a converter, electrically connected to the processor; and
forming a controller electrically connected to the converter, wherein the controller is configured to provide a second control signal comprising double pulses.

19. The method of claim 18, further comprising:
forming a signal isolator to generate a third control signal corresponding to the second control signal; and
forming a power isolator to provide a power supply to the testing circuit.

20. The method of claim 19, further comprising:
forming a first power unit, configured to adjust a first power supply voltage for generating a second power supply voltage; and
forming a second power unit, electrically connected to the first power unit, wherein the second power unit is configured to generate a third power supply voltage based on the second power supply voltage.

21. A semiconductor system for testing a semiconductor device, comprising:
a signaling circuit, configured to receive a first control signal from a processor; and
a testing circuit, electrically connected to the signaling circuit, wherein the testing circuit comprises:
a buffer, configured to transmit a fourth control signal to a second electrode of the semiconductor device, wherein the fourth control signal comprises voltages higher than those of a third control signal; and
a diode, electrically connected to a first electrode of the semiconductor device, wherein dynamic electrical testing is performed on the semiconductor device with turning on and off the diode for switching the semiconductor device.

22. The semiconductor system of claim 21, wherein the signaling circuit comprises:
a controller, configured to provide a second control signal for driving the semiconductor device corresponding to the first control signal.

23. The semiconductor system of claim 22, wherein the signaling circuit comprises:
a power isolator, electrically connected to the buffer; and
a signal isolator, electrically connected to the controller, wherein the power isolator and the signal isolator are configured to prevent the controller from being interfered by the switching of the semiconductor device.

24. The semiconductor system of claim 21, further comprising:
a power circuit, electrically connected to the testing circuit and configured to maintain the dynamic electrical testing.

25. The semiconductor system of claim 24, wherein the signaling circuit, the testing circuit, and the power circuit are physically separated with one another.
